(19) United States
(12) Patent Application Publication
(10) Pub. No.: US 2020/0248017 A1
(43) Pub. Date: Aug. 6, 2020

(54) Voltage Variable and Electrical Overstress Protection Materials for 3D Printing or Additive Manufacturing

(71) Applicant: tri/REX, LLC, Austin, TX (US)

(72) Inventor: Kevin J. Hess, Austin, TX (US)

(21) Appl. No.: 16/779,158

(22) Filed: Jan. 31, 2020

Related U.S. Application Data
(60) Provisional application No. 62/799,670, filed on Jan. 31, 2019.

(51) Int. Cl. C09D 11/101; C09D 11/52; C09D 11/037; C09D 11/102; C09D 11/107; B33Y 70/10; H05K 9/00

(52) U.S. Cl. CPC C09D 11/101; C09D 11/52; C09D 11/037; H05K 9/0081; C09D 11/107; B33Y 70/10; C09D 11/102

(57) ABSTRACT

Resin compositions or formulations curable by UV or visible radiation have voltage-variable material (VVM) properties and/or electrical overstress (EOS) material properties. The resins may be used to construct or fabricate structures, articles, components, devices, or objects, either as standalone items or as a component(s) of larger structures or devices, using 3D printing or additive manufacturing (AM), such as in LED- or laser-based digital light projection (DLP) systems and laser-based stereolithography (SLA) systems. These items or components may be applicable for electrostatic dissipation, electrostatic discharge (ESD), or other EOS purposes.

### CROSS-REFERENCE TO RELATED APPLICATIONS

This application claims the benefit of U.S. Provisional Application No. 62/799,670, filed Jan. 31, 2019.

### FIELD OF THE INVENTION

The invention is generally related to voltage variable and conductive materials and structures, and, more particularly, to metal particle- or conductive fiber-filled, light-curable liquid resin compositions for forming structures and devices by 3D printing or additive manufacturing (AM) that afford some protection due to high current excursions or electrostatic discharge (ESD).

### BACKGROUND

Materials polymerized by free radical processes and cationic processes with thermal or light energy have been used in a myriad of applications. For 3D printing or additive manufacturing (AM), except for post-print curing, thermally driven free radical polymerization processes typically are not used. Instead, light or photocurable, free radical polymerizable materials are used in 3D printing or AM, and these materials typically have sensitivity to ultraviolet (UV) to visible light in the wavelength range of 365 nm to 405 nm. Such materials generally are based on acrylate functional or functionalized constituents that are free-radically polymerized by a radical generating photoinitiator when exposed to a specified irradiation dose from a modulated or controlled UV or visible light source. The acrylate carbon-carbon double bonds are very reactive and provide a curing speed adequate for 3D printing or AM processes. Further, these free-radically reacting resins may not continue to cure when the irradiation source is turned off. Cationically polymerizable resins, such as epoxies, on the other hand, have been used for decades in photo-curing ink applications. Once photoinitiated, the cationically propagating polymer chain continues to react even after the irradiation source is turned off. Further, the cationic “center”, which is the active end of the cationic polymer chain, does not terminate by combination and does not easily terminate by environmental contaminants other than water or bases.

Although polymer-based voltage variable materials (VVMs) have found applications, prior polysiloxane, epoxy, acrylate, or epoxy-acrylate hybrid resin compositions (i.e., a hybrid material composed of both free radical and cationic polymerizable materials) typically have been formulated for slow, thermal curing processes. These prior disclosed compositions are not known for UV to visible light photopolymerization as used in 3D printing or AM. Moreover, other than in flood lighting exposure systems, available AM resin compositions are not known to include metal or conductive particles, which offer advantages as will be described herein.

U.S. Patent Application Publication No. 2018/0057414 ('414 patent application) describes light-curable ceramic slurries with hybrid binders. The '414 patent application defines “hybrid binder” at paragraph [0011] as comprising a light-curable organic resin and a reactive siloxane, the two materials capable of copolymerizing. At paragraph [0016], the '414 patent application describes light-curable organic resin components as being acrylates, epoxies, oxetanes, vinyl ethers, thiols and combinations thereof. Photoinitiators compatible with the described organic resin components are disclosed at paragraph [0019], including cationic photo acid generators and free radical photoinitiators. At paragraph [0020], the '414 patent application describes ceramic particles or ceramic filler that may be combined with the organic resin components to form a light-curable slurry. The '414 patent application describes, starting at paragraph [0034], various compositions of alumina and organic resin components that are photo-cured to form intermediary “green” ceramic articles that are then “debinded” by heating to decompose the cured resin system, leaving behind the alumina and the polysiloxane component described above. Conductive or metal particles or fillers, however, are not taught or suggested by the '414 patent application.

U.S. Pat. No. 9,982,164 ('164 patent) describes resin compositions for 3D printing of objects. The compositions include a photoinitiator and resin compatible with the photoinitiator. A “latent” polyurea resin, comprising two or more reactive components that are inhibited from reacting with one another, are included in the composition. For example, a blocked diisocyanate and an amine are disclosed. The blocked isocyanate is prevented from reacting by a blocking agent. The blocking agent is dissociated thermally in a post printing cure step. This de-blocks the isocyanate group, which then can proceed to react with the amine to form a polyurea. For example, at C4:L4, the '164 patent describes an epoxy-based, dual cure system that includes a “latent” polyurethane or polyurea. At C4:L33, the '164 patent describes another dual cure system with a “latent” polyurethane or polyurea. And at C11:L36 to C13:L47, the '164 patent also discloses “tougheners,” such as impact modifiers used in polymerizable resins. Most of the tougheners disclosed are impact modifiers that may be incorporated into the formulation and are compatible with acrylate and epoxy resins. But polyurethane and polyurea used as “tougheners” are not taught or suggested in the '164 patent.

U.S. Pat. No. 4,726,991 ('991 patent) discloses voltage variable resin compositions in which a polymer matrix includes a metal particle dispersed therein. The '991 patent describes the functional performance and compositions of the final voltage variable resistance materials, but does not describe any formulations that are cured in place or 2D or 3D printed.

U.S. Pat. No. 4,977,357 ('357 patent) discloses cured voltage variable resin compositions in which an elastomer is crosslinked or cured in sheet form after mixing with a metal powder. Similar to the '991 patent above, the '357 patent discloses the functional performance and compositions of the final voltage variable resistance materials, but does not describe any formulations that are cured in place or 2D or 3D printed.

U.S. Pat. No. 5,099,380 ('380 patent) and U.S. Pat. No. 6,981,319 ('319 patent) describe applications for VVMs employed in electrical connectors. The materials disclosed exhibit a high resistivity at voltages below a determined level and a low resistivity at voltages above the determined level. In the '380 patent, a pre-formed sheet of resin containing metal powder is fitted around a connector pin and placed in contact with a grounded metal connector case. Upon the occurrence of a sufficiently high voltage discharge event, the disclosed VVM experiences a transition from resistive to conductive and shunts the charge to ground. The '319 patent discloses forming curable resin compositions that are thermally reacted after being coated or screen printed onto a surface, but neither photo-curing resins nor 3D printing or AM are taught or suggested.

### SUMMARY

In accordance with embodiments of the invention, the concepts disclosed herein may provide improvements and advantages over those disclosed in the patents described above or other prior art.

Depending on formulation, in accordance with embodiments of the invention, metal particle- or conductive fiber-filled resin compositions described herein may be used in 3D printing or AM for the production of voltage variable and conductive materials or structures. These VVMs and conductive materials may be used, for example, as a component(s) of fuses for interrupting current flow when there is a high current excursion or as a component(s) of electrostatic dissipative or electrostatic discharge (ESD) protection devices providing a ground or shunt path to dissipate charge when there is a high voltage excursion. Resin compositions, as described herein, are particularly suitable for AM by which structures, objects, components, films, thin sheets, tubes, enclosures, etc. may be fabricated inexpensively in high volume without the need for injection molding equipment, molds, or tooling.

In accordance with certain embodiments of the invention, curable resins may contain metal particles or fibers, other conductive or semiconductive particles or fibers, or like additives as components, as described herein. These components also may block curing light, and once the polymerization reactions are initiated by the photo (illumination) light source, the reactions of the materials or resins may be robust enough for polymerization to continue even where the light is blocked. These reactions may also continue after being initiated and exposure by the light source has ended. Such materials would be compatible for AM processes using lithography.

### BRIEF DESCRIPTION OF THE DRAWINGS

FIG. 1 illustrates a chemical formula for an oxetane-based monomer, where R1 represents a carrier structure, such as an aliphatic chain, aromatic ring, or other organic structure, in accordance with embodiments of the invention.

FIG. 2 illustrates a chemical formula for an oxirane-based monomer, where R1 represents a carrier structure, such as an aliphatic chain, aromatic ring, or other organic structure, in accordance with embodiments of the invention.

FIG. 3 illustrates a chemical formula for an acrylate-based monomer for free radical polymerization, where R1 represents a carrier structure, such as an aliphatic chain, aromatic ring, or other organic structure, in accordance with embodiments of the invention.

FIG. 4 illustrates a chemical formula for a photo acid generator, such as a diaryl iodonium salt, where R represents ring substitutions, such as amino groups, methyl groups, and/or hydroxyl groups, I+ represents a cation, such as an iodine cation, and X− represents a counter anion, for example, hexafluorophosphate, in accordance with embodiments of the invention.

FIG. 5 illustrates a free radical photoinitiator, a benzophenone, to create a radical species when exposed to UV irradiation, in accordance with embodiments of the invention.

FIG. 6 schematically illustrates an expected off-state to on-state resistivity transition of a polymerized or cured VVM resin when a transient (trigger or threshold) voltage (or charge) level is reached due to an EOS or ESD event, in accordance with embodiments of the invention.

### DESCRIPTION OF THE INVENTION

This application claims the benefit of U.S. Provisional Application Ser. No. 62/799,670, filed Jan. 31, 2019, which is incorporated herein by reference in its entirety.

The proposed materials described herein may be photocured in a 3D printer or AM system that provides a UV or visible light source (for example, at 355 nm or approximately at 355 nm, which means within Δλ nm of 355 nm, i.e., 355 nm±Δλ nm with Δλ=5 nm, as used herein). These proposed formulations may be prepared using process steps and methods that are otherwise known in the industry, such as mixing, blending, compounding, and formulating of the compositions, resins, or materials. In accordance with embodiments of the invention, depending on the weight percentage of metal particles, metal compounds, conductive fibers, etc. used in the material formulations, as described herein, some specialized milling or compounding equipment may be needed to help form the curable resin formulations.

In accordance with embodiments of the invention, the proposed free radical and cationic polymerizable resins, compositions, formulations, materials, etc. advantageously may be photo-cured or photo-polymerized by free radical or cationic reaction processes or mechanisms. Cationic curing epoxy resins beneficially and advantageously may offer, for example: (1) initiation and propagation reactions resistant to oxygen poisoning, which allows for extended (dark) curing; (2) reduced cure shrinkage over acrylates, which lessens warpage and internal stresses; and/or (3) reduced yellowing over acrylates due to the use of the cationic photoinitiator systems.

The extended or dark curing cationic reactions mentioned above means the polymerization reactions continue after the UV or visible photo source is removed or shut off, and the resin is no longer being exposed to UV or visible radiation. This dark curing characteristic may be advantageous for curing compositions containing particles and other light blocking agents because the “live” reaction center of the polymer may continue to propagate through the resin and continue the curing process after light exposure ceases.

Embodiments of the present invention offer voltage variable properties or passive electrostatic dissipative or discharge properties in a resin system that are compatible for use in 3D printing or AM. The electrical properties of the certain embodiments of the disclosed resin compositions include voltage variable resistivity (VVR) (or its inverse, i.e., voltage variable conductivity (VVC)) useful for forming cured apparatus, elements, structures, or objects whose electrical properties may change from being predominantly electrically resistive to predominantly electrically conductive. Such variable electrical characteristics exhibited by these apparatus, elements, structures, or objects, when in the presence of, or when exposed or subjected to, a voltage potential, may provide for their beneficial electrostatic dissipative or discharge properties. In other words, the VVR properties may be used for controlled electrical discharge, such as discharging static electricity. Moreover, the mechanical properties of the cured compositions also may provide manufactured apparatus, elements, structures, or objects having desirable or advantageous flexural rigidity, impact resistance, or elastic structural properties, as described herein.

### Exemplary Material Composition Embodiments

In accordance with embodiments of the invention, the material compositions or resins disclosed herein may comprise cationically polymerizable compositions or formulations of:
A1. A cationically polymerizable monomer(s) that may have aliphatic, aromatic, cycloaliphatic, arylaliphatic or heterocyclic structure and comprising one or more groups suitable for acid catalysis or cationic propagation, including, but not limited to epoxide groups, glycidyl groups, oxirane groups, oxetane groups, vinyl ether groups, etc. Other suitable polymerizable monomers include, but are not limited to, heterocyclic monomers, including lactones, lactams, cyclic acetals, cyclic thioethers, Spiro orthoesters, vinylethers, thietanes, tetrahydrofurans, oxazolines, 1,3-dioxepane, oxetan-2-one, etc., and olefins such as methoxyethene, 4-methoxystyrene, styrene, 2-methylprop-1-ene, 1,3-butadiene, diglycidyl ether bisphenol A (DGEBA), aliphatic oligomers of glycidyl ether, aliphatic ring epoxides, such as (3,4,-epoxy cyclohexylmethyl-3,4-epoxycyclohexame carboxylate, 2-ethyl-2-hydroxymethyl oxetane, etc., and/or combinations thereof;
A2. Optionally, the A1 monomer(s) and/or combinations thereof may be combined with a co-monomer(s) (or with combinations of the co-monomers) having functional groups suitable for acid catalysis or cationic propagation;
B. A photoacid generator(s) (a photoinitiator(s)) (PAG(s)) (generally ionic or non-ionic), examples of which include, but are not limited to, onium salts, sulfonium and iodonium salts, etc., such as diphenyl iodide hexafluorophosphate, diphenyl iodide hexafluoroarsenate, diphenyl iodide hexafluoroantimonate, diphenyl p-methoxyphenyl triflate, diphenyl p-toluenyl triflate, diphenyl p-isobutylphenyl triflate, diphenyl p-tert-butylphenyl triflate, triphenylsulfonium hexafluororphosphate, triphenylsulfonium hexafluoroarsenate, triphenylsulfonium hexafluoroantimonate, triphenylsulfonium triflate, dibutylnaphthylsulfonium triflate, etc., and including mixtures of any of the above PAGs; the PAG(s) is sensitive to irradiation with UV or visible wavelengths (for example, at 355 nm or approximately at 355 nm, as above). Suitable photoacid generators include, for example, Ciba Specialty Chemicals Irgacure 250, triarylsulphonium salts, such as Dow Cyracure UVI-6976, Cyracure UVI-6992, Degussa Degacure K185, or other sulphonium salts, such as, Quang Li Chem QL Cure 211 and QL Cure 212, Asahi Denka SP-150, IGM Omnicat 550, and Ciba lrgacure MacroCAT. Suitable PAGs for use with visible wavelengths of light include, for example, ferrocenium salt compounds, iodonium salt compounds in combination with silanes, such as tris-(trimethylsilyl) silane, and sensitizing dyes, for example, violanthrones, thioxanthenes, perylenes, anthroquinones, diketopyrrolopyrroles, etc.

In accordance with other embodiments of the invention, the material compositions or resins may comprise free radically polymerizable compositions or formulations of:
A′1. A free-radically polymerizable monomer(s) that may have aliphatic, aromatic, cycloaliphatic, arylaliphatic or heterocyclic structure and comprises one of more groups suitable for free radical reaction or propagation, including, but not limited to, acrylates, methacrylates, such as isobornyloxyethy methacrate or lauryl methacrate, acrylamides, styrenics, olefins, halogenated olefins, cyclic alkenes, maleic anhydride, alkenes, alkynes, carbon monoxide, functionalized oligomers, monomers with multiple different reactive functionalities, functionalized polyethylene glycols and polyols, etc., and/or including combinations thereof;
A′2. Optionally, the A′1 monomer(s) and/or combinations thereof may be combined with co-monomers having functional groups suitable for free radical reactions;
B′. A free radical photoinitiator(s) (PI(s)), examples of which include, but are not limited to, benzoins, such as benzoin, benzoin ethers, benzoin acetate, acetophenones, benzil, benzil ketals, anthraquinones, triphenylphosphine, benzoylphosphine oxides, benzophenones, thioxanthones and xanthones, acridine derivatives, phenazene derivatives, quinoxaline derivatives, triazine compounds, etc., including mixtures thereof; the PI(s) is sensitive to irradiation with UV or visible wavelengths (for example, at 355 nm or approximately at 355 nm, as above). Suitable free radical photoinitiators for the visible wavelengths of light include, but are not limited to, phosphine oxide in combination with silanes, such as tris-(trimethylsilyl) silane, etc.

The polymerizable compositions described above, comprising combinations of: (1) the A1 monomer(s) and the B photoinitiator(s); (2) combinations of the A′1 monomer(s) and the B′ photoinitiator(s); and (3) combinations of the A1 monomer(s), B photoinitiator(s), A′1 monomer(s), and B′ photoinitiator(s), may be further combined with additives, as described herein, that imbue useful and advantageous properties to the final resin formulation(s) or composition(s), either before or after polymerization or curing.

Certain of these advantages may be obtained by dispersing electrically conductive or semiconductive metal filler materials, particles, and/or compounds uniformly in the resin(s), for example, to aid in electrically dissipative or discharge processes, such as in ESD applications. Optionally, dispersant or dispersing aids or agents, such as titanates, organosilanes, or the like may be added beneficially or advantageously to help reduce or prevent agglomeration of the metal particles or compounds. For example:
C. Particles or compounds of electrically conductive or semiconductive materials, that may comprise metal(s), metal compound(s), metal fillers, metal filaments, inorganic material(s), organic material(s) and/or a composite or mixture thereof, may be dispersed in the polymerizable compositions, materials, formulations or resins. Suitable metal particles include, for example, Ni, Al, Ag, Cd, Cu, Pd, Fe, W, bronze, etc. In embodiments having metal compounds, exemplary metal compounds may include Ni carbonyl particles, such as INCO type 255 powder, Si carbide, Pb titanate, Pb zirconate, Ba titanate, Zr carbide, Ta carbide, Ti carbide, W carbide, boron carbide. In embodiments having organic materials, exemplary organic materials may be carbon black, carbon fiber, graphite, graphene, carbon nanotubes or nanostructures, fullerenes, and the like. In some embodiments, these additives may be surface treated with a glycidyl silane or titanate to improve wetting of the particles by the resin and dispersion of the particles in the resin matrix. In some other embodiments, these additives may be surface treated with a photocatalyst, such as titanium dioxide, to promote the activation of the photoinitiator(s). In yet other embodiments, photocatalyst particles, such as particles of titanium dioxide, may be dispersed in the compositions, materials, formulations, or resins for the same reason.

These particles or compounds may be of any suitable shape, including, but not limited to, spherical, elliptical, cylindrical, fiber-like, irregular, etc. They may have any useful or desirable aspect ratio (e.g., length-to-diameter ratio or length-to-width ratio), for example 1:1 to 100:1 or higher. The particles or compounds may have sharp edges, irregular edges, fingers, dendrites, or the like that enhance the entanglements or electrical interactions between adjacent particles.

The particles or compounds may be of any suitable size (for example, ranging from 10 nm to 30 μm in average diameter or preferably in the range of 0.1 to 20 μm in average diameter. The particles or compounds, if present in the compositions, formulations or materials, maybe 5-70% by weight of the composition(s), formulation(s), or materials with the remaining weight % comprising the base resin(s) of A+B or optionally comprising the modified resin(s) of A′+B′, or optionally comprising the hybrid resin(s) of A+A′+B+B′, and any or all of components from groups D-I below (also see Tables I-IV below).

Preferably, such metal particles or metal compounds may be dispersed homogeneously and uniformly throughout the resin(s). The quality of the dispersion may be determined by at least one of these factors: (a) visual inspection of cured, polymerized test samples, viewed in cross-section; (b) electrical characterization (for example, resistivity per ASTM D257-DC); or (c) viscosity response of the dispersion versus time during the mixing step of preparing the formulation. Dispersion “quality” may be affected by combinations of different filler material loadings, compounding and shear conditions, as well as filler material surface treatments and/or coatings.

The presence of such metal particles and/or metal compounds in the resin composition(s) or formulation(s) contemplated and described herein also may be desirable or advantageous, for example, to help reduce the peak temperature experienced by the resin composition(s) or formulation(s) during the polymerization reaction(s) compared to without their presence. The thermal conductivity of the metal particles or metal compounds further may help to spread or distribute the heat of reaction(s) spatially, which may enhance reaction uniformity. Moreover, including such metal particles or compounds may advantageously help reduce the required light illumination intensity for polymerization or curing processes and/or the number of post-processing steps needed to produce 3D printed or additive manufactured elements, structures, components, articles, or objects having desirable mechanical, electrical, and/or thermal properties, as described herein.

In accordance with embodiments of the invention, the resin composition(s) or formulation(s) described above, including the A1, A2, B, A′1, A′2, and B′ components, and/or combinations thereof, and further comprising combinations of them with the C group components, as well as with those optional D-I group components described below, may be useful for forming cured or polymerized elements, structures, components, articles, or objects. Although not limited in application, the material composition(s) or formulation(s) may be cured or polymerized by photo-based 3D printing or AM systems. Non-limiting examples of photo illumination sources for the curing or polymerization processes include LEDs, solid state lasers, dye lasers, chemical lasers, Hg lamps, Xenon lamps, halogen lamps, or the like. In these photo-based processes, it may be advantageous to control the duration, intensity, and profile of the radiation from such photo sources. In some embodiments, a hard mask may be used to block transmission of the radiation. In other embodiments, a Digital Light Projector (DLP) or micro-mirror device may be used for spatial and temporal exposures to the light. In yet other embodiments, prisms, mirrors, reflectors, lenses, filters, shutters, choppers, spatial or light modulators, or the like, and/or multiple axis motion control systems may be used to control the radiation.

In accordance with some embodiments of the invention, for the resin formulation(s) or composition(s) described herein, 3D printing processes may use laser, LED, or other photo illumination sources with a DLP-based control system. For resin exposure and polymerization, such sources may provide illumination by light at a wavelength or wavelengths within the UV or visible wavelength spectrum, such as 200 nm to 430 nm, or preferably 340 nm to 405 nm, or more preferably 355 nm to 405 nm. It should be understood that the wavelength or wavelengths contemplated for such use in these wavelength ranges may be approximately at such wavelength or wavelengths, as described above.

Optionally and advantageously, other components may be added to the composition(s) or formulation(s) to modify the light curing process or final properties of the cured material. In one embodiment, for example, a property-modifying resin, such as a polyurethane resin or a polyurea resin, advantageously may be added to the composition(s) or formulation(s) to increase the impact strength, resistance to fracture, or flexibility of the cured material. In other embodiments, a light absorbing agent or light blocking agent advantageously may be added to reduce the curing rate or depth of penetration of the light radiation into the resin(s) per exposure. In yet other embodiments, a photosensitizing agent absorbing at wavelengths other than at the primary light exposure wavelength (e.g., longer than 355 nm if 355 nm is the primary exposure wavelength), depending on the photosensitizer used, advantageously may be added to increase the efficiency of the photoinitiator to initiate or catalyze the curing reaction.

### Specific Exemplary Material Composition Embodiments:

In accordance with some embodiments of the invention, the polymerizable composition(s) or formulation(s) may comprise a cationically polymerizable component (A1), an acid generating polymerization initiator (B), and dispersed metal particles or metal compounds (C). For example, in certain of these embodiments, as described above, the monomer(s) may include epoxide groups, glycidyl groups, oxirane groups, oxetane groups, vinyl ether groups, etc. A polymerizable component may be a cycloaliphatic di-epoxy, oxetane or vinyl ether, for example, at 30-95 wt % of the total resin formulation or composition. A suitable photoacid generator (PAG), examples of which include, but are not limited to, onium salts, sulfonium, iodonium salts, etc., may be included at 0.1-5 wt % based on the polymerizable component(s) of the resin(s) formulation. The PAG may be capable of interacting with UV wavelengths (or visible wavelengths, as described above) to generate an acid catalyst. Suitable metal particles or metal compounds may include Ag, Al, Ni, or SiC, for example, at 5-70% by weight of the total resin formulation(s) or composition(s).

In accordance with embodiments of the invention, the A1 and B components described above represent a cationically polymerizable composition(s) or formulation(s). In accordance with other embodiments of the invention, the polymerizable composition(s) or formulation(s) may comprise free radically polymerizable components A′1 and a free radical generating polymerization initiator B′, and dispersed metal particles of metal compounds C. For example, in some of these embodiments, as described above, the A′1 monomer(s) may include acrylate groups, methacrylate groups, styrenics groups, vinyl groups, and/or vinyl ether groups. A polymerizable A′1 component may be a cycloaliphatic di-acrylate, tert-butyl-styrene, or vinyl ether at 30-95 wt % of the total resin formulation(s) or composition(s). A suitable free radical initiator, examples of which include, but are not limited to, acetophenones, benzophenones, isoxanthones, etc., may be included at 0.1-5 wt % based on the polymerizable component(s) of the resin formulation(s) or composition(s). Suitable metal particles or metal compounds may include Ag, Al, Ni, or SiC, for example, at 5-70% by weight of the total resin formulation(s) or composition(s).

In accordance with other embodiments of the invention, combinations of cationic and free radical polymerizable formulations may be advantageous. In one such embodiment, epoxy monomer(s) (A1) and acrylate monomer(s) (A′1) may be polymerized by cationic initiator(s) (B) and free radical initiator(s) (B′), respectively. Such embodiments, comprising both cationic and free radical polymerization mechanisms are termed “hybrid” resins or compositions, formulations, or materials. The polymerizable monomer(s), A1 and A′1, may be present in the resin formulation(s) or composition(s) at weight ratios in the range of 10:1 to 1:10 for the ratio of A1:A′1. For example, the A1 monomer(s) may be included in the resin formulation(s) or composition(s) in an amount that is 10 times that of the A′1 monomer(s). In embodiments, as described herein, in which two different polymerization or curing processes or mechanisms are employed, such as the hybrid cationic and free radical processes, one mechanism will be termed the “primary mechanism” and the second mechanism will be termed the “secondary mechanism” (e.g., see Table IV below). It should be understood that these two processes or mechanisms of curing may take place concurrently or sequentially, depending on the desired or designed curing process(es) or mechanism(s).

In accordance with embodiments of the invention, formulation or composition additives or elements in groups D through I below (also see Table IV) desirably or advantageously may be added to modify the cationic, free radical, hybrid formulation(s) or composition(s), or their permutations, as described above:
D. Optionally, low molecular weight polymers or oligomers, including dimers, trimers, etc. having similar functional groups suitable for acid catalysis or cationic propagation may be included at 0.5-30% by weight based on the polymerizable component(s) of the resin formulation(s) or composition(s), for example, glycidyl-terminated low molecular weight polyethers, epoxidized low molecular weight polybutadiene, or oxetane-terminated low molecular weight polysiloxanes.
E. Optionally, molecular weight control agents, such as crosslinking or chain transfer agents may be included at 0.5-30 wt % based on the polymerizable component(s) of the resin formulation(s) or composition(s). Crosslinking agents comprise a monomer(s) with two or more functional groups that are compatible to react with the photoinitiated monomer(s), such as a triglycidyl aromatic crosslinking agent or the like. Suitable other cross-linking agents include, for example, low molecular weight glycidyl methacrylate oligomers, preferably trimers triglycidyl-p-aminophenol or N,N,N,N-tetraglycidyl-4,4-methylenebis benzylamine. Chain transfer agents that terminate the propagating chain end, but preserve the reactive photoinitiator site, may be used to control average molecular weight (MW) and MW distribution and help to provide desirable or advantageous mechanical and/or thermal properties. Suitable chain transfer agents include, for example, alcohols or diols, such as ethylene glycol or a low molecular weight polyol.
F. Optionally, a viscosity modifier(s) may be included to control the viscosity of the final formulation(s) or composition(s) such that it may be compatible with the process(es) used to cure or polymerize it. Non-limiting examples of viscosity modifiers include: thixotropic agents, such as fumed silica, or branched polymers, such as polysiloxanes, dissolved into the monomer(s), co-monomer(s), or combinations thereof, as described above; long chain linear polymers dissolved into the monomer(s), co-monomer(s), or combinations thereof, as described above; and gelling agents, such as a semicrystalline polymer(s), for example, syndiotactic polystyrene, that may be dissolved in the monomer(s), co-monomer(s), or combinations thereof, as described above, when heated and then gel when cooled. Such viscosity modifiers may be included at 0.1-20 wt % based on the polymerizable component(s) of the resin formulation(s) or composition(s).
G. Optionally, a photoreaction modifier(s) may be included, such as photo-blockers and/or photo-absorbers, such as dyes, pigments, or the like, or photosensitizers or accelerators that interact with the light used for curing or polymerization and are capable of absorbing energy at other light wavelengths (e.g., at longer wavelengths) than the photoinitiator absorbs, such as thioxanthene. For example, Lambson Speedcure CPTX or the like may be included at 0.1-5 wt % based on the polymerizable component(s) of the resin formulation(s) or composition(s). The photosensitizer(s) may be active with the photoacid generator(s) or, if present, the free radical generator(s). The photoreaction modifier(s) may also be a light blocking agent that selectively limits penetration of the light radiation into the resin bulk. In embodiments where visible light is used for curing the resin composition, light blocking pigments, such as carbon black may be used.
H. Optionally, an impact property or thermal property modifier(s) may be included, such as an elastomer, rubber, or other resin, where the modifier(s) may be functionalized with functional groups compatible to react with the monomer(s), co-monomer(s), or combinations thereof, as described above. Non-limiting examples of the modifier(s) include silicones, siloxanes, polysiloxanes, polyureas, polyurethanes, or the like. For example, a polyurethane comprising the reaction product of an aromatic diisocyanate, a diol chain extender, and a functionalizing agent, such as a glycidyl functional amine, silanol, or carbamate, may be included at 1-30 wt % based on the polymerizable component(s). In accordance with certain embodiments of the invention, the impact modifying agent, polyurethane, may be formed by the reaction of a blocked isocyanate function material with a polyol after the element, component, structure, article, or object is 3D printed or additively manufactured and post-cured at a temperature above the printing (photocuring) temperature. In some embodiments, the printing temperature may be, for example, 25° C. and the post-curing temperature may be 100° C.
I. Optionally, a pigment(s), dye(s), photosensitizer(s), or active color-changing compound(s) may be included and suspended or solubilized in the liquid resin formulation(s) or composition(s). Suitable pigments include, for example, carbon black, titanium dioxide, and phthalocyanine compounds. In accordance with certain embodiments of the invention, a tracer or detectable compound(s) (e.g., fluorescent, phosphorescent, radioactive, or the like), or combinations thereof may be included that are useful for tracking or identifying, by known detection techniques, resin formulation(s) or composition(s) or elements, components, structures, articles, or objects constructed or fabricated therefrom as described herein. For example, a tracer visible under black light irradiation may be included in the resin formulation(s) or composition(s). In accordance with yet other embodiments of the invention, the detectable compound may react with the polymerizing material(s) described herein or may undergo a change in response to the polymerization reaction(s) during curing or due to a temperature change of the resin formulation(s), composition(s), or material(s) during preparation, storage, handing, processing, or post-processing, thus allowing detection. Such pigment(s), dye(s), photosensitizer(s), or active color-changing compound(s) may be included at 0.1-10 wt % based on the polymerizable component(s) of the resin formulation(s) or composition(s).

In accordance with embodiments of the invention, the electrical properties of the resin formulation(s) or composition(s) described above may be adjusted by changing the weight percentage of the C group particles or compounds, and may depend on the type of these particles or compounds incorporated into the compositions. In one embodiment, the cured resin(s) may have a base resistivity of 10⁵-10¹⁵ ohms-cm and a variable resistivity ranging between 1-200 ohm-cm when an electrical potential is applied across or discharged through the polymerized or cured material. Such a material may be useful for electrostatic dissipative or electrostatic discharge (ESD) applications, as described herein. In accordance with other embodiments of the invention, the cured resin(s) may have a sufficient weight percentage of conductive particles or compounds, for example, exhibiting a base resistivity of 0.1-200 ohms-cm even in the absence of an applied potential. Such material(s) may be useful for electrostatic dissipative or ESD applications where static electric charges are dissipated passively along the surface or through the bulk of the polymerized or cured resin element, component, structure, article, or object. Such or similar material(s) having even higher amounts of conductive particles or compounds may also be useful for protection or shielding for electromagnetic interference (EMI), as described below.

In accordance with certain embodiments of the invention, the mechanical properties of the above resin formulation(s) or composition(s) may be adjusted by changing the type and weight percentage of the monomer(s), optional co-monomer(s), or combinations thereof, as described above, group E molecular weight control agent(s), and group H impact modifier(s). For example, the impact strength (resistance to breaking upon impact) of a resin composition of A1 and B may be increased by adding an elastomer from the component group H. For example, the flexural rigidity and thermal resistance of a resin composition of A′1 and B′ may be increased by adding metal particles or compounds from group C and a suitable cross-linking agent from the component group E. Various embodiments may provide a flexural modulus between and inclusive of 1 and 80 GPa, a heat distortion temperature (HDT) between and inclusive of 23 and 280° C., and/or an impact strength between and inclusive of 1 and 50 Nm. In accordance with yet other embodiments of the invention, it may be advantageous for the cured formulation(s) or composition(s) to exhibit a flexural modulus of less than or equal to 1 GPa, such that they may be deformed by compression between, for example, two flat metal plates or electrical contacts. Such a compressed, low resistivity formulation(s) or composition(s) may provide an electrical path between the two metal plates or electrical contacts in which, for example, one contact may be to ground. The resin formulation(s) or composition(s) exhibiting both low resistivity and low flexural modulus may be useful for shielding an electronic or electrical component(s) or assembly(ies) from EMI or other EOS events. These resin formulation(s) or composition(s) may be formed or constructed for an EMI shield or be used in conjunction with other components, such as a metal case, can, plate, or the like, to form or construct an EMI shield for electronic or electrical component(s) or assembly(ies).

### Exemplary Chemical Materials and Structures for Certain Embodiments:

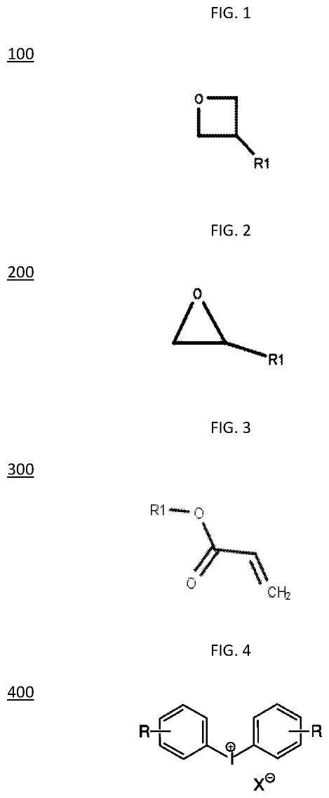

A1, A2. A monomer(s), co-monomer(s), or combinations thereof may be, for example, oxetane-based 100 (FIG. 1) or oxirane-based 200 (FIG. 2) for cationic polymerization, where R1 represents a carrier structure, such as an aliphatic chain, aromatic ring, or other organic structure.
A′1, A′2. A monomer(s), co-monomer(s), or combinations thereof may be, for example, acrylate-based 300 (FIG. 3) for free radical polymerization, where R1 represents a carrier structure, such as an aliphatic chain, aromatic ring, or other organic structure.
B. A photoacid generator(s) may be, for example, a diaryl iononium salt 400 (FIG. 4), where R represents ring substitutions, such as amino groups, methyl groups, or hydroxyl groups, I⁺ is an iodine cation, and X⁻ is a counter anion. A nonlimiting example of a photoacid generator is BASF Irgacure 250, where the R groups are methylene and/or sec-butylene groups and the counter anion is phosphorous hexafluoride.
B′. A free radical photoinitiator may be a benzophenone 500 (FIG. 5) to create a radical species when exposed to UV irradiation.

### Exemplary Application Embodiments of the Voltage Variable Materials (VVMs):

Various devices and methods are known for providing protection of circuitry from transient electrical overstress (EOS) disturbances. For present purposes, an EOS transient can be defined as a transient voltage or current condition that can damage or upset normal operation of circuits. Electrical overstress transients of practical concern may arise from electrostatic discharge (ESD), which is relatively commonplace. Such transients, or pulses, may rise to their maximum amplitudes in periods ranging from less than a few nanoseconds to several microseconds, and may be repetitive.

Exemplary devices requiring EOS protection include computer, networking, and telecommunications equipment; cell phones, handheld electronics, and home entertainment electronics; automotive, aerospace, and industrial electronics and control systems; and equipment used in the assembly of electronic components and devices, including robotic grippers, handlers; storage and shipping trays; testing and probing stations used for quality assurance, etc.

The purpose of an EOS or ESD protective device is to shunt electrical transients to ground before the energy resulting from the transient can damage the protected circuitry. Such protective devices include fuses, spark gaps, varistors, Zener diodes, transzorbs, thin-film devices, bypass capacitors, inductors, filters, semiconductor diodes, transistors, or combinations thereof. The protective devices are connected between a circuit to be protected and ground, or between a conducting line leading to a circuit to be protected and ground.

A common overstress transient may reach voltages exceeding 20,000 volts and currents of more than 40 amperes. Such electrostatic transients may reach peak discharge voltages in less than a few nanoseconds and can upset or destroy electronic components in computers and other electronic devices. In addition to such transients, lightning is another example of an EOS transient capable of adversely affecting electronic or electrical circuits.

In accordance with embodiments of the invention, EOS or ESD protection devices have material characteristics that demonstrate a high resistivity when subjected to normal operating voltages and currents and a low resistance when subjected to an EOS or ESD event, such as a high voltage discharge or high current event. When such materials, such as some of the resin formulations, compositions, and materials disclosed herein, are in a higher resistivity (or lower conductivity) state, these materials are said to be in an “off-state”; when these materials are in a lower resistivity (or higher conductivity) state compared to the off-state, the materials are said to be in an “on-state.”

In accordance with certain embodiments of the invention, termed “active,” the polymerizable VVM formulations or compositions described herein may provide the following electrical performance characteristics in the off-state and the on-state, and, respectively, not during and during electrostatic dissipative, ESD or other EOS events:

### (a) Active ESD (Active Dissipative):

(a.1.) Off-state Electrical Resistivity (ASTM D257-DC) Value: 10⁵ to 10¹⁵ ohms-cm.
(a.2.) On-state Electrical Resistivity (i.e., increased Conductivity) (ASTM D257-DC) Value: 1-200 ohms-cm.
(a.3.) Active electrostatic dissipative, ESD, or EOS event performance meeting IEC 61000-4-2-X, 4 kV and 8 kV direct discharge, 16 kV air discharge, per Human Body Model, Machine Model, and/or Charged Device Model ESD test standards.

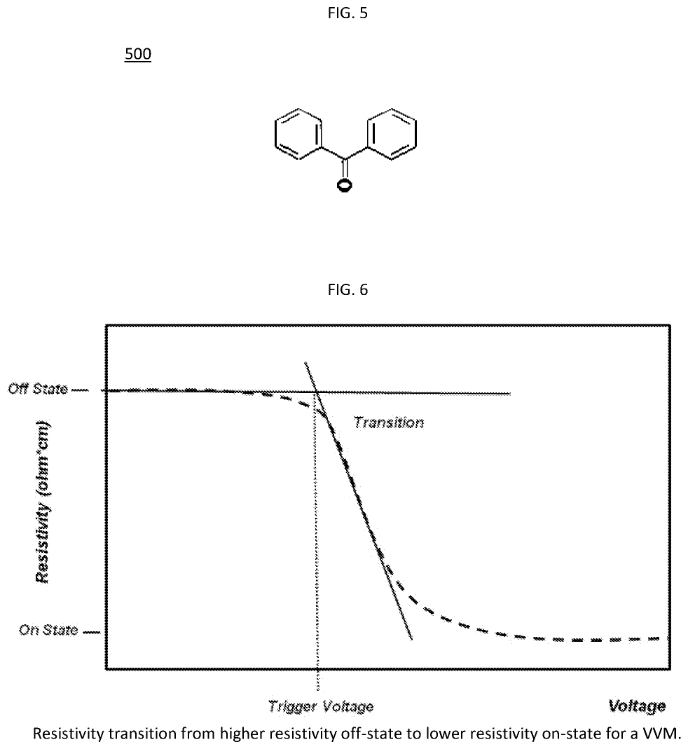

In some applications, an electrostatic dissipative, ESD, or EOS event protection device incorporates the materials having the material characteristics described above that demonstrate being “active” with the on-state and “inactive” in the off-state (see, for example, FIG. 6 below). Such materials would provide a conductive path for the movement of electrostatic charges to ground when in the on-state as a result of the lowering of the resistivity.

In accordance with embodiments of the invention, a resin formulation(s) or composition(s) may be photocured, 3D printed, or additively manufactured in a shape as or for a component or device that is advantageous for providing ESD or EMI protection. For ESD protection, it may be used as a component of a fuse, such as a fuse body or component. The shape or component or device (e.g., the fuse body for ESD protection) may be 3D printed or additively manufactured using light at a wavelength in the range of 355 nm to 405 nm (or approximately at the chosen wavelength in the range, as described above) for LED or laser-based DLP or laser-based 3D printing, for stereolithography (SLA), or for an AM system, or using light in such systems at a different wavelength or in one of the wavelength ranges described above. For the fuse body, it then may be joined with electrodes, a first electrode connected to ground to provide a pathway to shunt charge and a second electrode not connected directly to the first electrode but connected to the circuit or device requiring protection.

In accordance with other embodiments of the invention, termed “passive,” the resin formulation(s) or composition(s) may exhibit a lower resistivity than those described above, and the 3D printed or additive manufactured device or component based on these resins instead may passively discharge electrostatic charge build-up while maintaining the capability of high voltage transient protection, or may provide EMI protection. Such resin formulation(s) or composition(s) may provide the following electrical performance characteristics:

### (b) Passive ESD (Static Dissipative)

(b.1.) Electrical Resistivity (ASTM D257-DC) Value: 0.1 to 200 ohms-cm.

In accordance with embodiments of the invention, an exemplary application for passive dissipative materials would be in the forming of storage and transport trays for electronic components, such as semiconductor devices and the like that may be susceptible to damage from low levels of static electric charge buildup. Another example of an application is in the electronic assembly of components and printed circuit boards, where robot apparatus for gripping, handling, moving, transporting electrostatic charge sensitive components must not themselves accumulate any charge that might be transferred to the components. In this or other applications, forming a grip or handling contacts with a VVM with low resistivity may be beneficial, for example, to grip or contact components and through which built-up electrostatic charges may be safely discharged.

In accordance with embodiments of the invention, a resin formulation(s) or composition(s) having sufficiently high conductivity (or sufficiently low resistivity) due to the amount of included metal or conducting particles or compounds may be used for shielding of electronic or electrical components or devices from electromagnetic interference (EMI). Here, the cured resin(s) may provide for an electrical pathway or connection between two or more conductive structures or contacts (or ground), such as metal plates, shields, printed circuit board contacts, etc. when the material is placed in contact with two or more of said structures. An exemplary structure using such materials would be a conductive gasket or O-ring incorporated into electrical connectors or electrical shields for protection from EMI.

In accordance with certain embodiments of the invention, the VVMs or resin compositions or formulations for use in the various applications described herein, as well as in other applications, advantageously may be formulated and designed to meet certain thermal and mechanical properties, such as the following:

(a) Heat Distortion Temperature (HDT) (ASTM D648) Value: ≥110° C. (0.46 MPa loading)

### (b) Flexural Modulus, Strength, Elongation (ASTM D790) Value: 0.5-2.5+ GPa

### (c) Tensile Modulus, Strength, Elongation (ASTM D638) Value: 10-50+ MPa

(d) Hardness—(ASTM D2240) Value: Shore A hardness 20 Durometer

Tables I-IV below summarize various possible constituents of the resin formulation(s) or composition(s) described above in accordance with embodiments of the invention.

TABLE I
Base Formulations for Cationic Polymerization Resins.

| | | | Cationic |
|---|---|---|---|
| Component | Weight | | Formulation |
| Type | % ⁽¹⁾ | Notes | (Primary Cure) |
| Monomer(s) | 30-95% | Monomer(s) for Cationic | A1 |
| | | reaction. | |
| Co-monomer(s) | | Co-monomer(s) for Cationic | A2 |
| | | Cure reaction. | |
| Photoinitiator | | Initiator for Cationic Cure | B |
| | | Reaction. | |
| Metal Particles | 5-70% | Optionally surface treated | C |
| | | or coated. | |

⁽¹⁾ Weight percent for overall composition of Base Formulation desired.

TABLE II
Base Formulations for Free Radical Polymerization Resins

| | | | Free Radical |
|---|---|---|---|
| Component | Weight | | Formulation |
| Type | % ⁽¹⁾ | Notes | (Primary Cure) |
| Monomer(s) | 30-95% | Monomer(s) for Free Radical | A′1 |
| | | Cure reaction. | |
| Co-monomer(s) | | Co-monomer(s) for Free | A′2 |
| | | Radical Cure reaction. | |
| Photoinitiator | | Initiator for Free Radical | B′ |
| | | Cure Reaction. | |
| Metal Particles | 5-70% | Optionally surface treated | C |
| | | or coated. | |

⁽¹⁾ Weight percent for overall composition of Base Formulation desired.

TABLE III
Base Formulations for Hybrid (Cationic/Free Radical) Polymerization Resins

| Component | Weight | | Cationic | Free Radical |
|---|---|---|---|---|
| Type | % ⁽¹⁾ | Notes | Component | Component |
| Monomer(s) | 30-95% | Monomer(s) for | A1 | A′1 |
| | 10:1 to | Respective Cure reaction. | | |
| Co-monomer(s) | 1:10 ratio | Optional Co-monomer(s) | A2 | A′2 |
| | of Cationic | for Respective Cure | | |
| | to Free | reaction. | | |
| Photo-initiator | Radical | Initiator for Respective | B | B′ |
| | | Cure Reaction. | | |

| | | | |
|---|---|---|---|
| Metal Particles | 5-70% | Optionally surface | C |
| | | treated or coated. | |

⁽¹⁾ Weight percent for overall composition of Base Formulation desired.

TABLE IV
Additives

| | | | | Free Radical |
|---|---|---|---|---|
| Component | Weight | | Cationic Formulation | Formulation |
| Type | % ⁽²⁾ | Notes | (Primary Cure) | (Secondary Cure) |
| Low | 0.5-30% | Polymer chains of 2-10 | D | D |
| Molecular | | repeat units, incorporating | | |
| Weight | | functionality compatible | | |
| Oligomer | | with the Primary and/or | | |
| | | Secondary Cure | | |
| | | Mechanism. | | |
| Molecular | 0.5-30% | Chain Transfer Agents, | E | E |
| Weight | | Crosslinking Agents | | |
| Control | | incorporating functionality | | |
| | | compatible with the | | |
| | | Primary and/or Secondary | | |
| | | Cure Mechanism. | | |
| Viscosity | 0.1-20% | Polymers, Gelling Agents, | F | F |
| Modifiers | | Thixotropic Agents. | | |
| Photo- | 0.5-10% | Photo-Blockers, Sensitizing | G | G |
| Reaction | | Agents Compatible with | | |
| Modifiers | | Photo-mechanism. | | |
| Impact or | 1-30% | Elastomers, Rubbers, | H | H |
| Thermal | | Elastomer Particles, | | |
| Property | | optionally incorporating | | |
| Modifiers | | functionality compatible | | |
| | | with the Primary and/or | | |
| | | Secondary Cure | | |
| | | Mechanism. | | |
| Pigments, | 0.1-20% | Carbon Black, Cyan | I | I |
| Dyes, Photo- | | Pigments, Titanium | | |
| Sensitizers | | Dioxide, iso-thioxanthene. | | |

⁽²⁾ Weight percent of Additive(s) based on sum of the weight of Base Formulation desired from Tables I, II, or III plus the weight of Additive(s).

In accordance with embodiments of the invention, FIG. 6 below schematically illustrates an expected off-state to on-state resistivity transition of a polymerized or cured VVM resin 600 as described herein when a transient (trigger or threshold) voltage (or charge) level is reached due to an EOS or ESD event.

The specific embodiments disclosed herein are merely exemplary, and it should be understood that within the scope of the appended claims, the invention may be practiced in a manner or manners other than those specifically described in these embodiments. Specifically, it should be understood that the claims are not intended to be limited to the particular embodiments or forms disclosed, but rather to cover all modifications, equivalents, and alternatives falling within the spirit and scope of this disclosure. Also, any structures, components, or process parameters, or sequences of steps disclosed and/or illustrated herein are given by way of example only and may be varied as desired. For example, for any steps illustrated and/or described herein that are shown or discussed in a particular order, these steps do not necessarily need to be performed in the order illustrated or discussed. Further, the various exemplary structures, components, or methods described and/or illustrated herein may also omit one or more structures, components, or steps described or illustrated herein or include additional structures, components, or steps in addition to those disclosed.

1. A radiation curable composition for forming voltage variable conductive or semiconductive materials or structures, comprising:
a mixture, comprising:
a cationically polymerizable monomer,
a photoacid generator, and
a conductive or semiconductive particle or fiber additive.

2. The composition of claim 1, wherein radiation exposure of the mixture forms a composite material comprising (i) polymerized material portions and (ii) conductive or semiconductive material portions.

3. The composition of claim 2, wherein the composite comprises a component of a fuse device.

4. The composition of claim 2, wherein the composite comprises a component of an electrostatic dissipative or electrostatic discharge (ESD) protection device.

5. The composition of claim 1, wherein the composition comprises an additive manufacturing (AM) resin or a 3D printing resin.

6. The composition of claim 1, wherein the additive comprises a metal particle or metal compound additive.

7. The composition of claim 6, wherein the composition further comprises a dispersant agent that reduces or prevents agglomeration of the metal particle or metal compound additive.

8. The composition of claim 1, wherein the monomer is polymerizable where radiation is blocked by a constituent of the composition.

9. The composition of claim 1, wherein the composition has dark curing characteristics.

10. The composition of claim 1, wherein the mixture further comprises a co-monomer having an acid catalysis or cationic reaction propagating functional group.

11. The composition of claim 1, wherein the mixture further comprises a free-radically polymerizable monomer.

12. The composition of claim 11, wherein the mixture further comprises a free radical photoinitiator.

13. The composition of claim 12, wherein the mixture further comprises a co-monomer having a functional group suitable for free radical reactions.

14. The composition of claim 1, further comprising low molecular weight polymers or oligomers having functional groups suitable for acid catalysis or cationic reaction propagation.

15. The composition of claim 1, further comprising a molecular weight control agent.

16. The composition of claim 1, further comprising a viscosity modifier.
